(19) United States
(12) Patent Application Publication
(10) Pub. No.: US 2006/0061497 A1
(43) Pub. Date: Mar. 23, 2006

(54) Bit rate conversion apparatus and method

(75) Inventors: Atsushi Matsumura, Kanagawa-ken (JP); Tomoya Kodama, Kanagawa-ken (JP); Noboru Yamaguchi, Saitama-ken (JP); Tatsuaki Iwata, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/227,253

(22) Filed: Sep. 16, 2005

(30) Foreign Application Priority Data
Sep. 17, 2004 (JP) P2004-271494

(51) Int. Cl. H03M 7/00

(52) U.S. Cl. 341/61

(57) ABSTRACT

A bit rate of encoded moving picture data is converted in a system including a main processor, at least one sub processor and a main memory. In the main processor, a data acquisition unit acquires the encoded moving picture data from the main memory, a data analysis unit analyzes the encoded moving picture data, and an analysis data creation unit creates analysis data based on an analysis result. In the at least one sub processor, an analysis data acquisition unit acquires the analysis data, and a conversion processing unit converts the bit rate of the encoded moving picture data based on the analysis data.

### CROSS-REFERENCE TO RELATED APPLICATIONS

This application is based upon and claims the benefit of priority from prior Japanese Patent Application No. 2004-271494, filed on Sep. 17, 2004; the entire contents of which are incorporated herein by reference.

### FIELD OF THE INVENTION

The present invention relates to a bit rate conversion apparatus and a method for converting a bit rate of encoded moving picture data.

### BACKGROUND OF THE INVENTION

MPEG-2 stream of digital broadcast recently started and is delivered with a high bit rate different from the standard bit rate of a DVD. As a result, the MPEG-2 stream cannot be directly stored in a DVD. Accordingly, after the digital broadcast is stored in a hard disk once, a bit rate of the digital broadcast is lowered as a bit rate storable in the DVD. Alternatively, a bit rate of the received digital broadcast is directly converted to the bit rate storable in the DVD.

Furthermore, there is a need to store more content from a digital broadcast by lowering the image quality (lowering the bit rate). For example, the contents are first watched with high quality, and then stored with low quality (without deletion). In this way, a bit rate conversion technique is desired.

The technique of bit rate conversion is an important technique, but its demand is lower than the demand for a decoder and an encoder. Accordingly, in general, the technique of bit rate conversion is realized by software instead of dedicated hardware.

For example, a technique to use a CPU model by which software can quickly execute processing of a large load is proposed (Japanese Patent Disclosure (Kokai) 2002-358289). In this CPU model, a plurality of SIMD (Single Instruction Multiple Data) processors of high speed are prepared, and the plurality of SIMD processors cooperatively execute processing.

Concretely, eight attached processing units (APU) each having the same ISA (Instruction Set Architecture), one processing unit (PU) controlling processing of the APU, and a dynamic random access memory (DRAM) for sharing are prepared. The APU communicates in real time by using the DRAM, and continues the processing.

Furthermore, as a method for controlling the bit rate in the bit rate conversion, one path rate control and two paths rate control exist. A quantization scale used for quantization processing is calculated using a generated bit counted in variable length encoding in order to reach a target bit rate. For example, in order to raise the accuracy of calculation, the quantization scale is calculated using a previously encoded quantization scale or a generated bit obtained from variable length decoding. In this way, a method for controlling the bit rate using past information (not the present information) is called one path rate control. As rate control used for the bit rate conversion, the one path rate control is general (Japanese Patent Disclosure (Kokai) 2003-264839).

On the other hand, a method for controlling bit rate by analyzing static information of all streams (For example, generated bit or average quantization scale of each picture) is called two paths rate control. In the two paths rate control, static information of all streams is analyzed. Accordingly, in comparison with the one path rate control, the performance is higher, and rate control of high quality is possible.

As mentioned-above, in case of the one path rate control, in comparison with the two path rate control, accuracy of rate control is low, and a quantization scale cannot be suitably calculated. In this case, accuracy of bit rate conversion also lowers. Accordingly, especially in one path rate control, a method for raising accuracy of bit rate conversion is desired.

### SUMMARY OF THE INVENTION

The present invention is directed to a bit rate conversion apparatus and a method for accurately converting the bit rate of encoded moving picture data without lowering the processing efficiency.

According to an aspect of the present invention, there is provided an apparatus for converting a bit rate of encoded moving picture data, comprising: a main processor configured to control bit rate conversion; at least one sub processor configured to execute the bit rate conversion based on an indication from said main processor; a main memory configured to store the encoded moving picture data; and a memory access controller configured to control data transfer between said main memory and said main processor and between said main memory and said at least one sub processor; wherein said main processor comprises: a moving picture data acquisition unit configured to acquire the encoded moving picture data from said main memory through said memory access controller; a data analysis unit configured to analyze the encoded moving picture data; and an analysis data creation unit configured to create analysis data based on an analysis result of said data analysis unit; wherein said at least one sub processor comprises: an analysis data acquisition unit configured to acquire the analysis data; and a conversion processing unit configured to convert the bit rate of the encoded moving picture data based on the analysis data.

According to another aspect of the present invention, there is also provided a method for converting a bit rate of encoded moving picture data stored in a system including a main processor and at least one sub processor, comprising: acquiring the encoded moving picture data in the main processor; analyzing the encoded moving picture data in the main processor; creating analysis data based on an analysis result in the main processor; acquiring the analysis data and the encoded moving picture data in the at least one sub processor; and converting the bit rate of the encoded moving picture data based on the analysis data in the at least one sub processor.

According to still another aspect of the present invention, there is also provided a computer program product, comprising: a computer readable program code embodied in said product for causing a computer to convert a bit rate of encoded moving picture data stored in a system including a main processor and at least one sub processor, said computer readable program code comprising: a first program code to acquire the encoded moving picture data in the main processor; a second program code to analyze the encoded moving picture data in the main processor; a third program code to create analysis data based on an analysis result in the main processor; a fourth program code to acquire the analysis data and the encoded moving picture data in the at least one sub processor; and a fifth program code to convert the bit rate of the encoded moving picture data based on the analysis data in the at least one sub processor.

### BRIEF DESCRIPTION OF THE DRAWINGS

FIG. 1 is a block diagram of a bit rate conversion apparatus 10 according to a first embodiment.

FIG. 2 is a block diagram of a first APU 106a.

FIG. 3 is a block diagram of functional components of a PU 102.

FIG. 4 is a block diagram of functional components of an APU 106.

FIG. 5 is a flow chart of processing of a conversion processing unit 216 according to the first embodiment.

FIG. 6 is a schematic diagram of parallel processing of APU 106a-106h.

FIG. 7 is a flow chart of processing of the conversion processing unit 216 of the APU 106 according to a second embodiment.

FIG. 8 is a schematic diagram of share processing of the APU 106a-106h.

FIG. 9 is a schematic diagram of flow of encoded data in a first stage.

FIG. 10 is a schematic diagram of flow of encoded data in a second stage.

FIG. 11 is a schematic diagram of moving picture data in a third stage.

FIG. 12 is a schematic diagram of moving picture data in a fifth stage.

FIG. 13 is a schematic diagram of moving picture data in a sixth stage.

FIG. 14 is a schematic diagram of sharing of processing for each APU 106.

FIG. 15 is a schematic diagram of processing of each APU 106 in case that each APU 106 takes charge of different processing.

FIG. 16 is a schematic diagram of processing of the bit rate conversion apparatus 10 according to a third embodiment.

### DETAILED DESCRIPTION OF THE EMBODIMENTS

Hereinafter, various embodiments of the present invention will be explained by referring to the drawings. The present invention is not limited to following embodiments.

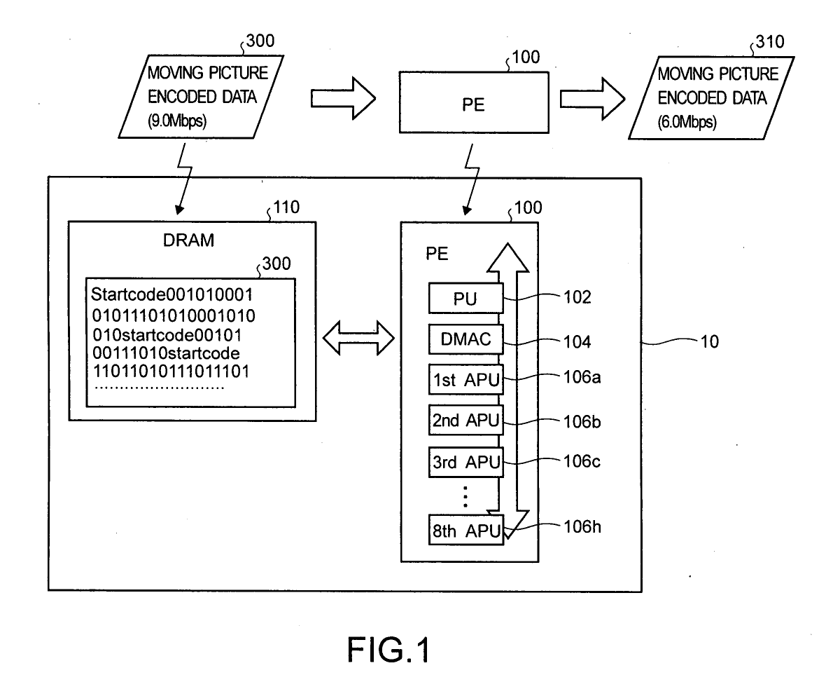

FIG. 1 is a block diagram of the bit rate conversion apparatus 10 according to the first embodiment. In the bit rate conversion apparatus 10, moving picture data 300 encoded by MPEG-2 is requantized, i.e., the bit rate is converted from 9.0 Mbps to 6.0 Mbps, and moving picture encoded data 310 of 6.0 Mbps is output.

In the first embodiment, moving picture data 300 encoded by MPEG-2 is a processing object. However, the processing object is not limited to this moving picture encoded data. Bit rate conversion can be executed for data encoded by another method. Furthermore, a value of the bit rate can be converted as an arbitrary value.

The bit rate conversion apparatus 10 comprises a processing unit (PE) 100 and a DRAM (Dynamic Random Access Memory) 110. Furthermore, the PE 100 comprises a processing unit (PU) 102, a DMAC (Direct Memory Access Controller) 104, and a plurality of attached processing units (APU) 106. In the first embodiment, eight APUs, i.e., a first APU 106a, a second APU 106b, . . . , an eighth APU 106h, are prepared.

The PU 102 corresponds to a main processor. The APU 106 corresponds to a sub processor. The DRAM 110 corresponds to a main memory. The DMAC 104 corresponds to a memory access controller.

In the bit rate conversion apparatus 10, moving picture encoded data, i.e., MPEG-2 elementary stream (9.0 MBPS) is acquired and stored in the DRAM 110. The PE 100 executes re-encoding of an MPEG-2 stream (stored in the DRAM 110), and generates the MPEG-2 stream of 6.0 Mbps. Then, the PE 100 writes a conversion result, i.e., moving picture encoded data 310 of 6.0 Mbps, into the DRAM 110. Last, the moving picture encoded data 310 of 6.0 Mbps is read from the DRAM 110 and output.

The PU 102 controls all functions of the PE 100. The DMAC 104 acquires moving picture encoded data from the DRAM 110, and sends the data to the PU 102 or the APU 106. Furthermore, the DMAC 104 sends data obtained from the PU 102 and the APU 106 to the DRAM 110. In this way, the DMAC 104 functions as an interface between the DRAM 110 and the PE 100. Each APU 106 executes processing of bit rate conversion in response to an indication from the PU 102.

Furthermore, eight APUs 106 execute parallel processing. Briefly, part data as a part of the moving picture encoded data is respectively assigned to each APU 106. Each APU 106 executes the same conversion processing of the part data. The parallel processing is explained afterward.

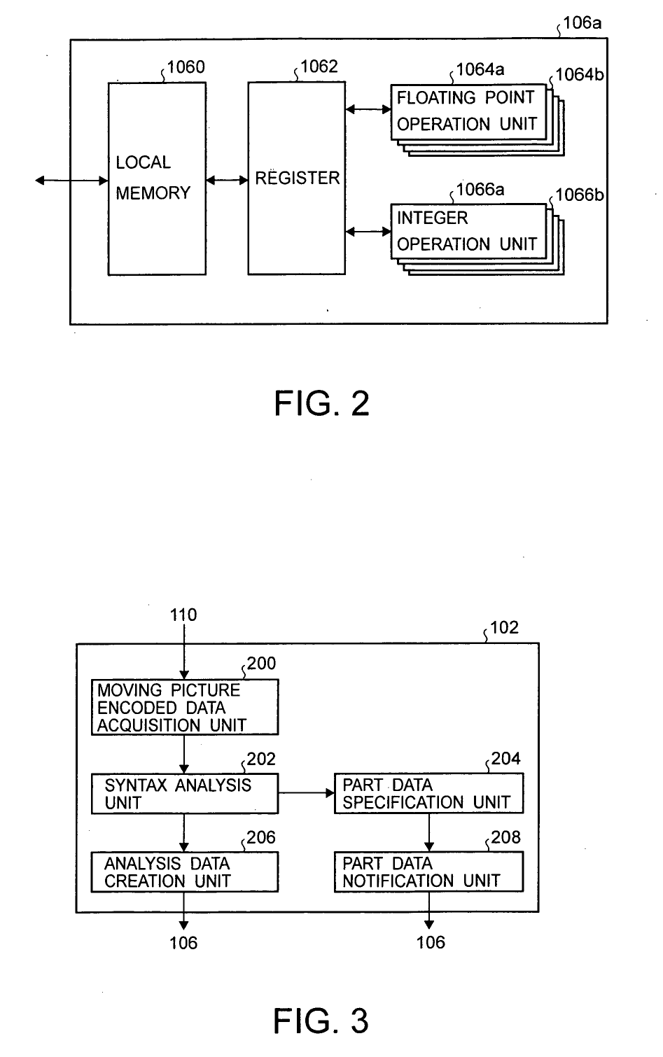

FIG. 2 is a block diagram of a first APU 106a shown in FIG. 1. The APU 106a comprises a local memory 1060, a register 1062, a first floating point operation unit 1064a, a second floating point operation unit 1064b, . . . , a first integer operation unit 1066a, a second integer operation unit 1066b,

The first APU 106a includes a plurality of floating point operation units and a plurality of integer operation units. The first APU 106a can quickly execute operation by cooperation of these operation units.

The local memory 1060 may consist of a relatively small SRAM (Static Random Access Memory) such as 128 kilo bytes. The APU 106 operates using program and data stored in the local memory 1060. Furthermore, the APU 106 requests the DMAC 104 to transfer data between the DRAM 110 and the APU 106. The APU 106 cannot directly access the DRAM 110 connected to the DMAC 104.

In case that the APU 106 executes a program, the PU 102 controls the DMAC 104 to transfer an object program and a stack frame from the DRAM 110 to the local memory 1060 of the APU 106. Next, the PU 102 issues a command to execute the program to the APU 106. Furthermore, the APU 106 sends processing results of the program to the DRAM 110 through the DMAC 104. When the processing is completed, the APU 106 instructs the PU 102 to generate an interruption representing completion of processing.

Detail components of the first APU 106a were explained by referring to FIG. 2. Detail components of the second APU 106b˜the eighth APU 106h are the same as the first APU 106a.

FIG. 3 is a block diagram of functional component of the PU 102. The PU 102 comprises a moving picture encoded data acquisition unit 200, a syntax analysis unit 202, a part data specification unit 204, an analysis data creation unit 206, and a part data notification unit 208.

The moving picture encoded data acquisition unit 200 acquires moving picture encoded data stored in the DRAM 110 through the DMAC 104. The syntax analysis unit 202 executes syntax analysis of the moving picture encoded data (acquired by the moving picture encoded data acquisition unit 200 from the DRAM 110). In the syntax analysis, a picture code, a slice start code and so on are detected. The analysis data creation unit 206 creates analysis data based on a syntax analysis result of the syntax analysis unit 202.

The part data specification unit 204 divides the moving picture encoded data into a plurality of part data to be assigned to each of the first APU 106a˜the eighth APU 106h. Concretely, the part data specification unit 204 determines amount of data to be assigned to each APU 106 in proportion to a capacity of the local memory 1060 of each APU 106. Based on the amount of data, the part data specification unit 204 specifies addresses corresponding to division points to divide the moving picture encoded data.

For example, if a capacity of the local memory 1060 of each APU 106 is equal and a throughput of each APU 106 is equal, the part data specification unit 204 may equally divide the moving picture encoded data and assign each divided encoded data to eight APUs 106.

Furthermore for example, if a capacity of the local memory 1060 of each APU 106 is different, many part data may be assigned to the APU 106 having the local memory 1060 of large capacity. If a throughput of each APU 106 is different, many part data may be assigned to the APU 106 of high throughput.

The part data notification unit 208 notifies addresses of part data specified by the part data specification unit 204 to the APU 106.

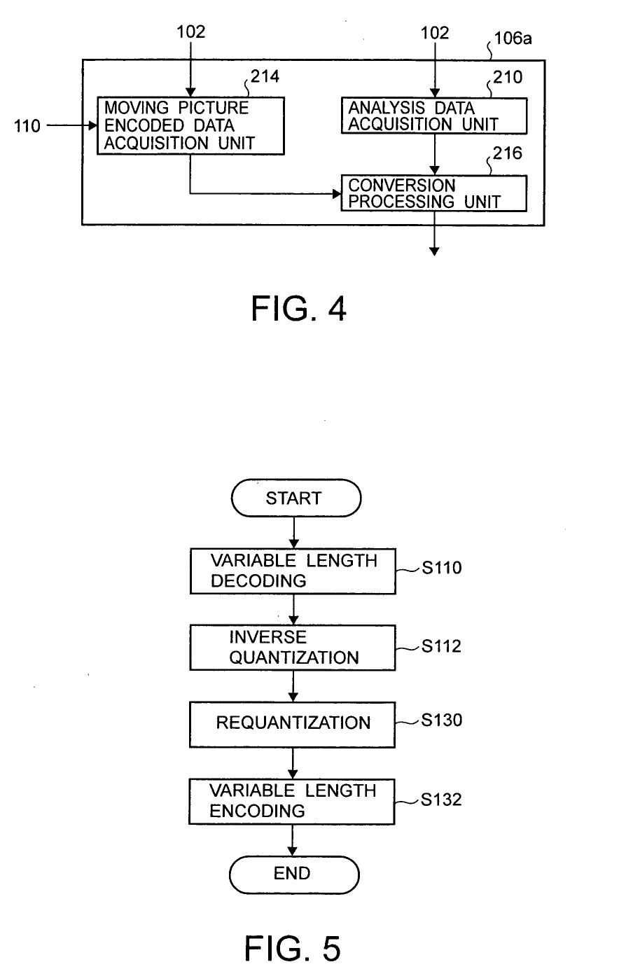

FIG. 4 is a block diagram of functional component of the APU 106. The APU 106 comprises an analysis data acquisition unit 210, a moving picture encoded data acquisition unit 214, and a conversion processing unit 216.

The analysis data acquisition unit 210 acquires analysis data created by the analysis data creation unit 206. The moving picture encoded data acquisition unit 214 acquires addresses of division points of part data from the part data notification unit 208 of the PU 102, and acquires the part data from the DRAM 110 through the DMAC 104.

The conversion processing unit 216 executes conversion processing of the part data (acquired by the moving picture encoded data acquisition unit 214) using the analysis data (acquired by the analysis data acquisition unit 210).

FIG. 5 is a flow chart of processing of the conversion processing unit 216. First, the APU 106 acquires moving picture encoded data through the DMAC 104, and executes variable length decoding (S110). As a result, the moving picture encoded data is decoded. Next, the APU 106 executes inverse quantization, and obtains DCT coefficient (S112).

Next, the APU 106 executes requantization (S130), and executes variable length encoding (S132). In this way, bit rate conversion is completed.

Furthermore, the conversion processing unit 216 executes control bit rate using analysis data (acquired from the analysis data acquisition unit 210). The analysis data includes various start codes (a picture start code, a slice start code) acquired by syntax analysis. These data are useful for rate control.

For example, by detecting a start code of each picture, generated bit spent for each picture is determined. In case of detecting a start code of each slice or each macro block, generated bit spent for each slice or each macro block is determined.

Furthermore, in addition to the start code, header information may be obtained as analysis data. For example, as for unit of a macro block, detail information such as a quantization scale and a motion vector of each macro block can be obtained from the header information.

Furthermore, for example, in case of proving a quantization scale before rate conversion, the rate conversion can be controlled using a value larger than the quantization scale. In other words, requantization is not executed using a value smaller than the quantization scale. Accordingly, useless increase of generated bit can be reduced.

Furthermore, for example, generated bit spent for encoding and the quantization scale may be obtained as analysis data. In this case, complexity of encoding may be calculated using the generated bit and the quantization scale. The complexity of encoding is represented as follows.
Complexity of encoding=(Generated bit)×(Quantization scale)

By using the complexity of encoding, bits smaller than a target bit rate are assigned to a scene easy for encoding, i.e., scene of which complexity of encoding is low. Furthermore, bits larger than a target bit rate are assigned to a scene difficult for encoding, i.e., scene of which complexity of encoding is high. In this way, variable bit rate can be accurately controlled.

As another example, the complexity of encoding may be calculated by analyzing a moving vector of macro blocks. In case of low generated bit for moving vector, i.e., if the moving vector of each macro block directs to a fixed direction, motion of an object is decided to be correctly tracked by motion detection. Accordingly, the complexity of encoding is low.

Conversely, in case of high generated bit for moving vector, i.e., if the moving vector of each macro block directs to various directions, motion of an object is not correctly tracked by motion detection. Accordingly, the complexity of encoding is high.

As mentioned-above, by using analysis data (obtained from syntax analysis) of encoded data stored in the DRAM 110, the APU 106 can execute bit rate conversion with high accuracy.

In the PE 100 of the first embodiment, in order to effectively execute bit rate conversion, the PU 102 and the APU 106 share processing of bit rate conversion. Concretely, the PU 102 takes charge of syntax analysis of MPEG of which operation load is relatively low. The PU 102 can quickly access the DRAM 110 through the DMAC 104. Accordingly, syntax analysis of a large number of MPEG-2 streams can be effectively processed.

Furthermore, the APU 106 takes charge of processing except for syntax analysis in bit rate conversion, i.e., processing from variable length decoding (S110) to variable length encoding (S132). Operation load of requantization processing (S130) is very large. As shown in FIG. 2, the APU 106 has many floating point operation units 1064 and many integer operation units 1066. Accordingly, conversion processing except for syntax analysis (S100) can be executed with high speed.

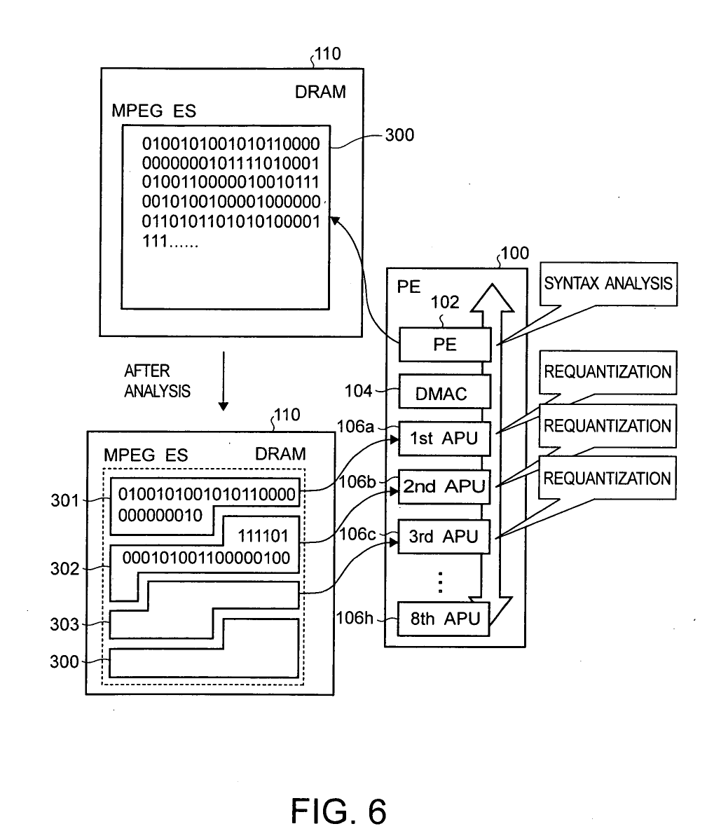

FIG. 6 is a schematic diagram of parallel processing of APU 106a-106h. The PU 102 divides MPEG-2 stream (obtained from the DRAM 110) based on capacity of the local memory 1060 of each APU 106. Then, the PU 102 assigns divided MPEG-2 stream 301, 302, 303, . . . , to each APU 106. Briefly, each APU 106 executes the bit rate conversion (such as requantization) of each part data 301, 302, 303, . . . , as a part of MPEG-2 stream.

Concretely, the part data specification unit 204 in the PU 102 obtains a picture start code (obtained by syntax analysis unit 202).

Then, the part data specification unit 204 specifies a division point to divide moving picture encoded data into a plurality of part data in each picture.

Each APU 106 obtains each part data 301, 302, 303, . . . , of each picture based on the division point. In conversion processing (including requantization) by the APU 106, each picture can be independently processed. Accordingly, by dividing each moving picture encoded data, each APU 106 can execute parallel processing.

As another example in MPEG-2, moving picture encoded data may be divided by unit of slice (Furthermore, in MPEG-4, moving picture encoded data may be divided by unit of video packet). Processing by unit of slice is effective for the case that all encoded data by unit of picture cannot be stored (capacity of the local memory 1060 in the APU is small) or the case that rate control is sensitively executed. Furthermore, in data division by unit of picture, feedback control of the rate control is executed by unit of picture. On the other hand, in data division by unit of slice, feedback control is executed by unit of slice. Accordingly, rate control can be realized with high accuracy.

Next, a bit rate conversion apparatus 10 of the second embodiment is explained. In the second embodiment, the bit rate conversion apparatus 10 execute bit rate conversion by reencoding.

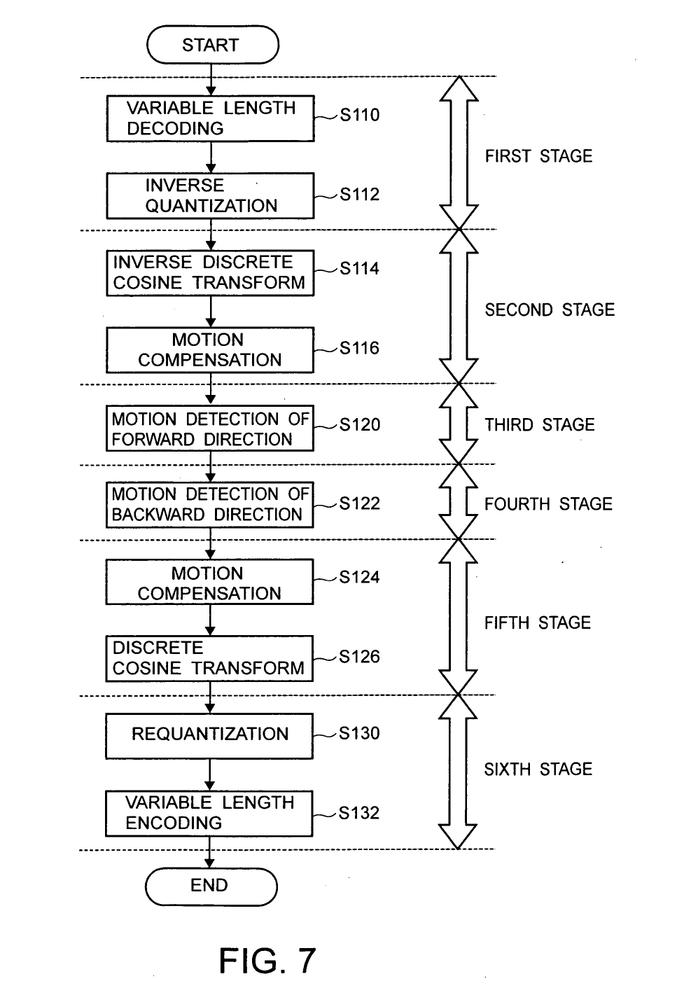

FIG. 7 is a flow chart of processing of the conversion processing unit 216 in the APU 106. In the bit rate conversion processing of the second embodiment, after inverse quantization (S112) explained referring to FIG. 5 in the first embodiment, inverse discrete cosine transform is executed for DCT coefficient, and a residual signal is obtained (S114). Next, based on the residual signal and a motion vector obtained by variable length decoding (S110), a decoded image is created by motion compensation (S116). By above encoding processing, a baseband video is created.

Furthermore, the following encoding is executed. Briefly, motion detection of forward direction (S120) and motion detection of backward direction (S122) are executed for the baseband video in order. Next, motion compensation is executed based on a motion vector obtained from the motion detection (S124). Next, discrete cosine transform is executed for a residual signal obtained from the motion compensation (S126). Next, requantization (S130) and variable length encoding (S132) are executed in order. In this way, bit rate conversion is completed.

In the same way as the PE 100 of the second embodiment, in case that many processing is included in bit rate conversion, in addition to assignment of motion picture data to the APU 106, by differing a kind of conversion processing of each APU 106, bit rate conversion can be further executed with high speed.

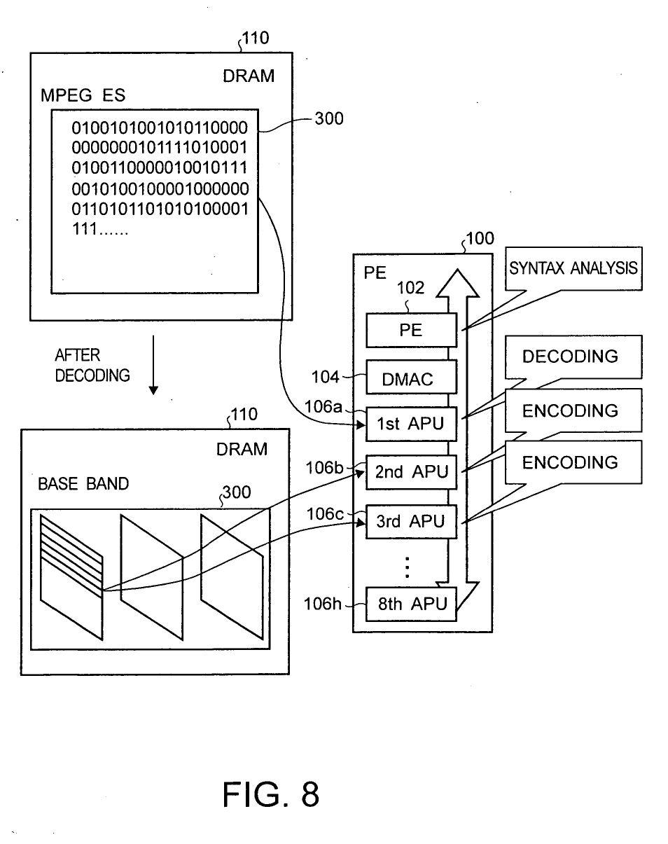

FIG. 8 is a schematic diagram of sharing processing of APUs 106a-106h. Concretely, in bit rate conversion processing, the first APU 106a takes charge of decoding while the second APU 106b and the third APU 106c take charge of encoding. In this way, by sharing processing among a plurality of APUs, bit rate conversion processing can be effectively executed.

In general, load of decode processing is smaller than load of encode processing. Accordingly, in the second embodiment, decode processing is assigned to one APU 106, and encode processing is assigned to two APUs 106.

Conversely, if decode processing is assigned to two APUs 106 and encode processing is assigned to one APU 106, speed of decode processing is faster than speed of encode processing. As a result, two APUs in charge of decode processing become under the condition of waiting, and bit rate conversion processing is not effective.

The APU 106 is not exclusively used for a decoder or an encoder, and can execute either function based on an indication from the PU102. Accordingly, instead of previous assignment of processing to each APU 106, processing to be assigned to each APU 106 may be changed based on status of each APU 106. In this case, even if the APU 106 becomes under non-effective condition as mentioned-above, by controlling processing of each APU 106, bit rate conversion processing can be effectively executed.

The sharing processing explained by referring to FIG. 8 is one example. The number of encoders and decoders assigned to each APU 106 may be arbitrary.

Furthermore, the PU 102 quickly accessing the DRAM 110 (relatively large capacity memory) may execute data analysis while the APU 106 quickly operating executes variable length decoding, inverse quantization, inverse DCT and motion compensation. In this case, decode processing can be effectively executed with high speed.

Furthermore, the PU 102 may execute syntax analysis while the APU 106 executes motion prediction, motion compensation, DCT, quantization and variable length encoding. In this case, encode processing can be effectively executed with high speed.

Furthermore, conversion processing may be divided into more processing than two processing (encoding and decoding). For example, conversion processing may be divided into six processing. Concretely, conversion processing is divided as follows; a first stage of variable length decoding (S110) and inverse quantization (S112); a second stage of inverse discrete cosine transform (S114) and motion compensation (S116); a third stage of motion detection of forward direction (S120); a fourth stage of motion detection of backward direction (S122); a fifth stage of motion compensation (S124) and discrete cosine transform (S126); a sixth stage of requantization (S130) and variable length encoding (S132).

While the APU 106 is executing the first stage, the local memory 1060 stores a program executed in the first stage, motion picture encoded data (processing object at the first stage), and reference data. When processing of the first stage is completed, the program and data are saved from the APU 106 to the DRAM 110 through the DMAC 104.

Next, a program to be executed in the second stage is written from the DRAM 110 into the APU 106 through the DMAC 104. In this way, access to the DRAM 110 is only executed at timing of change of each stage, i.e., from the first stage to the second stage, from the second stage to the third stage, and so on.

Processing included in each stage is determined based on capacity of the local memory 1060 of the APU 106 and operation speed of the APU 106. Briefly, processing of maximum data storable in the capacity of the local memory 1060 is set as one stage.

Decode processing includes several complicated processing. Accordingly, data of a program for software to realize the several complicated processing is large. Furthermore, in motion detection and motion compensation, a large scale memory is necessary because a large number of data, such as reference image, an object image, and a motion compensated image, are processed. Furthermore, in variable length decoding, a large scale memory is necessary because a variable length decoding table is preserved for processing.

On the other hand, if the capacity of the local memory 1060 is too small, program and data used for encode processing cannot be stored at one time in the local memory 1060. Accordingly, the APU 106 must dynamically obtain program and data from the DRAM 110 if necessary, and write them into the DRAM 110.

However, processing including access to the DRAM 110 takes a long time, and processing delay occurs as a whole. Accordingly, as mentioned-above, by minimizing frequency of access to the DRAM 110, processing delay due to access to the DRAM 110 can be avoided.

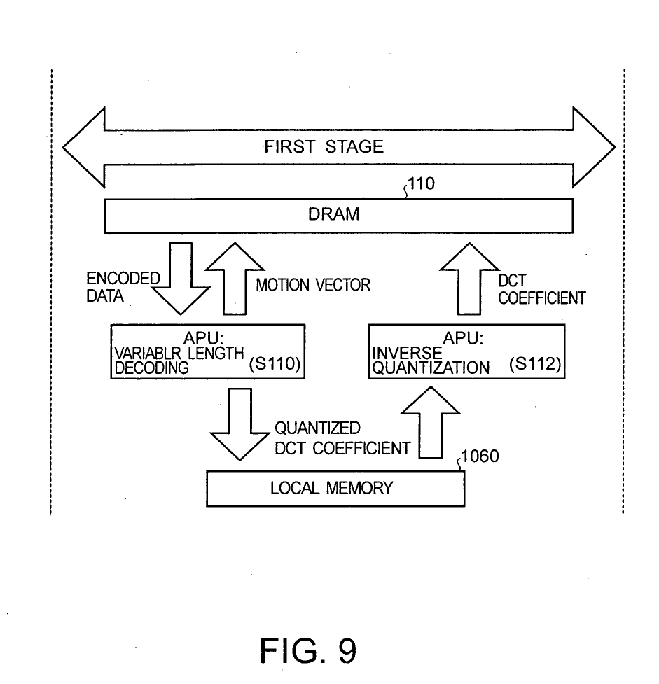

Hereinafter, by referring to FIGS. 9˜13, transfer of data in each stage is explained. FIG. 9 is a schematic diagram of encoded data flow in the first stage. In the first stage, the DMAC 104 acquires encoded data from the DRAM 110. In response to an indication from the PU 102, the DMAC 104 distributes the encoded data to each APU 106 by minimum unit of a slice. In this case, the slice is one line along horizontal direction on a static image of moving picture. Distribution of encoded data is explained afterwards.

Each APU 106 executes variable length decoding (S110) of encoded data received from the DMAC 104, and the local memory 1060 stores quantized DCT coefficient obtained by variable length decoding. Furthermore, each APU 106 executes inverse quantization (S112) of the quantized DCT coefficient stored in the local memory 1060. An inverse quantization result, i.e., DCT coefficient, is written to the DRAM 110 through the DMAC 104.

Variable length decoding processing (S110) refers to a variable length decoding table. Data capacity of this table is large, and almost possesses the local memory 1060. On the other hand, capacity to store a program of inverse quantization (S112) and data necessary for the program is small. Accordingly, inverse quantization and variable length decoding can be included in the same stage. As a result, these two processing are set as one stage.

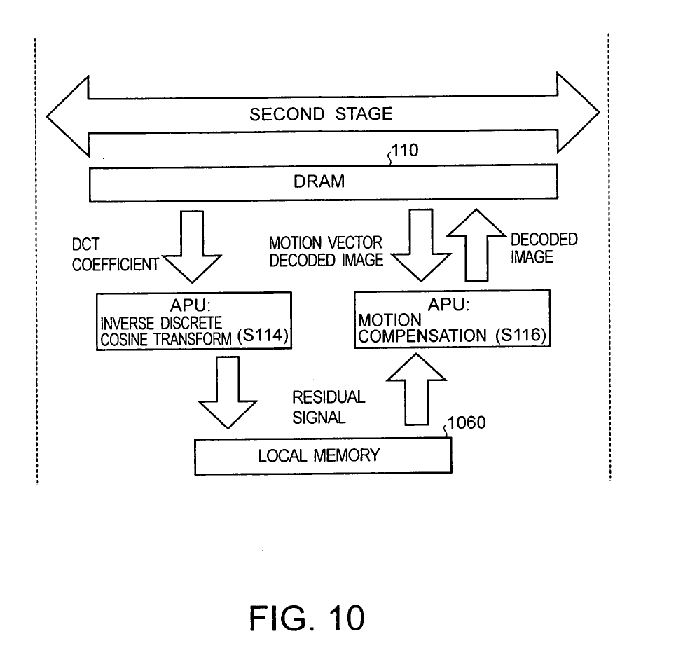

FIG. 10 is a schematic diagram of encoded data flow in the second stage. In the second stage, the APU 106 acquires DCT coefficient (obtained at the first stage) from the DRAM 110 through the DMAC 104. Then, the APU 106 executes inverse discrete cosine transform (S114) of the DCT coefficient, and the local memory 1060 stores a residual signal obtained by the inverse discrete cosine transform. Furthermore, the APU 106 acquires a motion vector and a decoded image as a reference from the DRAM 110, and executes motion compensation (S116) using the motion vector, the decoded image, and the residual signal (stored in the local memory 1060). A decoded image is created and written to the DRAM 110 through the DMAC 104.

In the inverse discrete cosine transform (S114) and the motion compensation (S116), data necessary for the decoded image (reference) and the residual signal corresponds to only one mode of each macro block. In comparison with an encoder, data necessary for these two processing is small. Accordingly, these two processing are set as one stage.

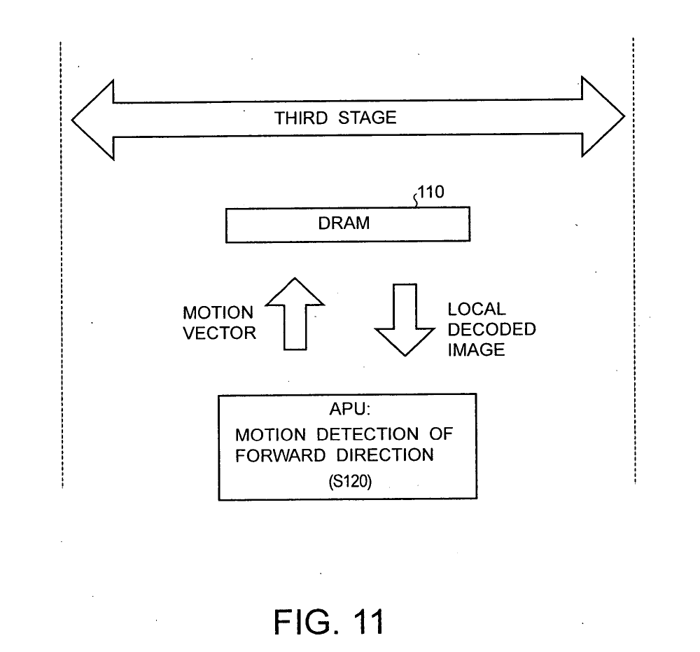

FIG. 11 is a schematic diagram of moving picture data flow in the third stage. In the third stage, each APU 106 acquires a local decoded image of moving picture data from the DRAM 110 through the DMAC 104. Then, each APU 106 executes motion detection of forward direction (S120). Motion vectors obtained by the motion detection of forward direction (S120) are written into the DRAM 110 through the DMAC 104.

Processing of the fourth stage is the same as moving picture data flow in the third stage shown in FIG. 11. Accordingly, the explanation is omitted.

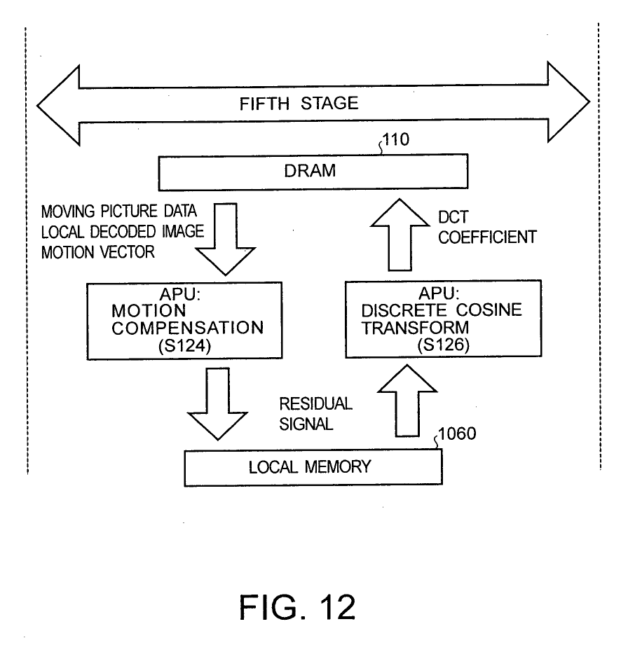

FIG. 12 is a schematic diagram of motion picture data flow in the fifth stage. In the fifth stage, each APU 106 acquires moving picture data, the local decoded image, and the motion vector from the DRAM 110 through the DMAC 104. The APU 106 executes motion compensation of the moving picture data, and the local memory 1060 stores a residual signal obtained by the motion compensation. Furthermore, the APU 106 executes discrete cosine transform processing (S126) of the residual signal stored in the local memory 1060. A result of DCT processing, i.e., DCT coefficient, is written into the DRAM 110.

In the motion compensation (S124), the moving picture data, the local decoded image, the motion vector, and the residual signal are processing object. Data capacity of this processing object is large, and almost possesses a capacity of the local memory 1060. On the other hand, in the discrete cosine transform processing (S126), data region maintained for the motion compensation (S124) can be used for storing DCT coefficient obtained by the discrete cosine transform processing (S126). Furthermore, a program of the discrete cosine transform processing is small. Accordingly, these two processing are set as one stage.

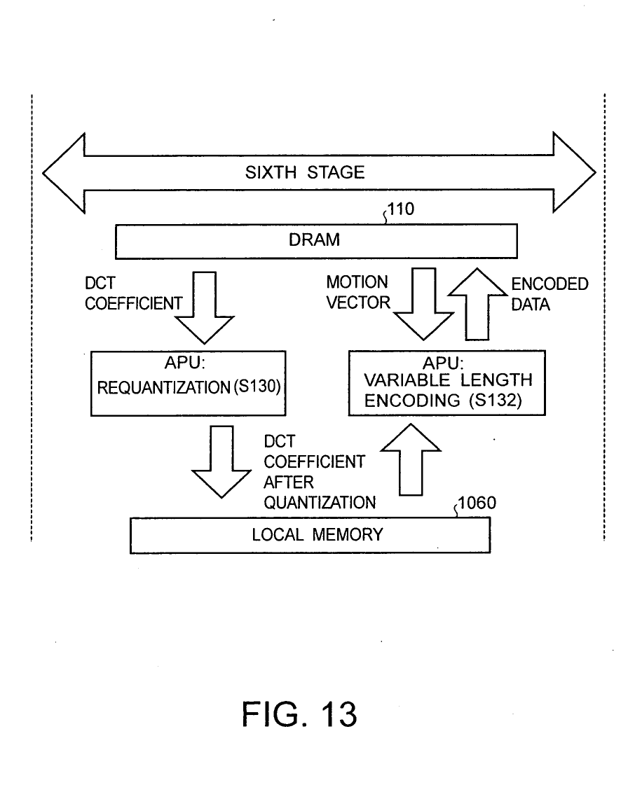

FIG. 13 is a schematic diagram of moving picture data flow in the sixth embodiment. In the sixth embodiment, each APU 106 acquires DCT coefficient from the DRAM 110 through the DMAC 104. The APU 106 executes requantization of the DCT coefficient (S130). The local memory 1060 stores a DCT coefficient as a quantization result.

Furthermore, each APU 106 acquires the motion vector from the DRAM 110 through the DMAC 104. Then, the APU 106 respectively executes variable length encoding (S132) of the motion vector and the DCT coefficient (stored in the local memory 1060).

In the requantization (S130) and the variable length encoding (S132), a capacity to store the program and the data is relatively small. However, in the variable length encoding (S132), data of the table used is relatively large. Accordingly, these two processing are set as one stage.

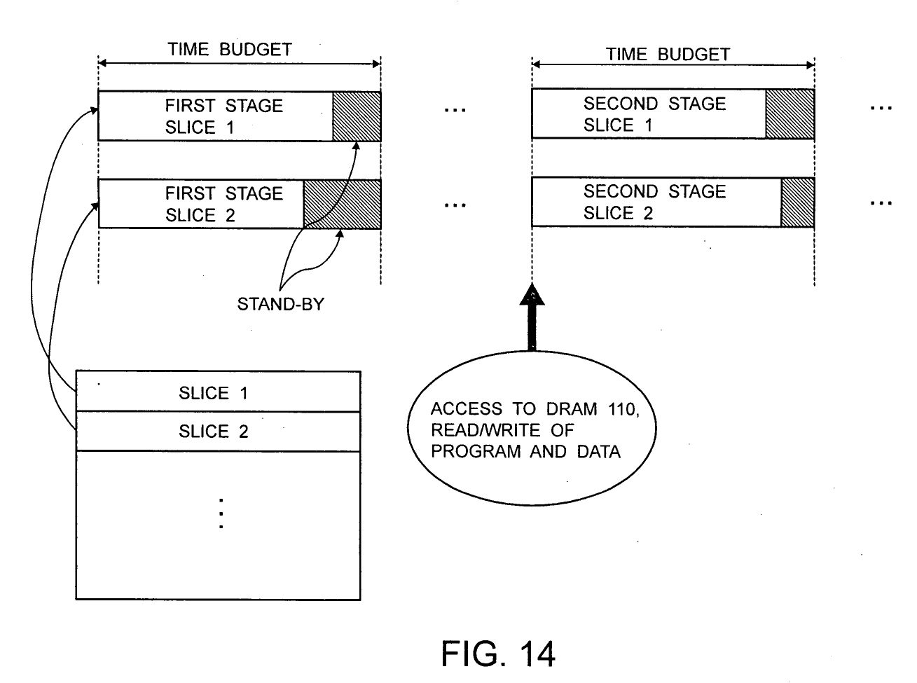

FIG. 14 is a schematic diagram of assignment of processing to each APU 106. As shown in FIG. 14, a time budget to control timing is set to the APU 106. Each APU 106 executes same processing to a different slice at same time budget. The slice is one line along a horizontal direction on a static image of a moving picture.

For example, processing of slice 1 is assigned to the first APU 106a. Processing of slice 2 is assigned to the second APU 106b. In this way, a plurality of APUs 106 parallely shares processing of one moving picture.

At the first stage, the first APU 106a executes variable length decoding and inverse quantization of a slice 1, and writes the slice 1 (variable length decoded and inverse quantized) to the DRAM 110. Furthermore, the second APU 106b executes variable length decoding and inverse quantization of a slice 2, and writes the slice 2 (variable length decoded and inverse quantized) to the DRAM 110. In the same way, each APU 106 executes variable length decoding and inverse quantization of the assigned slice, and writes the slice (variable length decoded and inverse quantized) to the DRAM 110.

As mentioned-above, a plurality of APUs 106 shares processing by unit of slice, and processing can be executed with high speed.

If a number of slices is larger than a number of APUs 106, a plurality of slices may be assigned to one APU 106. For example, slices 1˜3 are assigned to the first APU 106a, and slices 4˜6 may be assigned to the second APU 106b.

When the first APU 106a completes processing of the first stage, it often happens that the second APU 106b does not complete processing of the first stage. For example, when the first APU 106a completes processing of the first stage, the second APU 106b is executing processing of a slice 4. Otherwise, operation quantity of processing of each APU 106 is often different for the same slice.

In this case, while the second APU 106b processes the slice 4, the first APU 106a processes a slice 6. In comparison with the case that the second APU 106b processes slices 4˜6, processing can be executed at a high speed. In this way, if processing speed of each APU 106 is different, by reassigning slices to each APU 106, processing can be executed at a high speed.

In the second embodiment, moving picture data is assigned to each APU 106 by unit of slice. However, assignment unit of moving picture data to each APU 106 is not limited to the slice, and may be another unit. For example, moving picture data may be assigned to each APU 106 by unit of a macro block as a small unit composing the slice. Furthermore, in case of MPEG-4, moving picture data may be assigned to each APU by unit of a video packet.

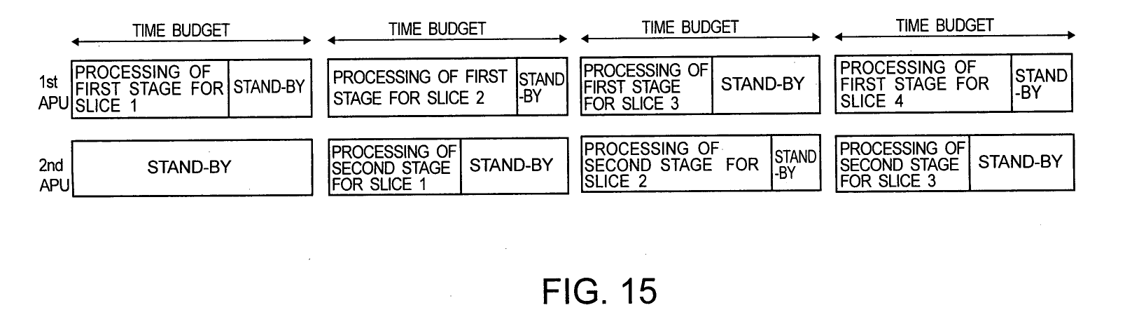

FIG. 15 is a schematic diagram of processing of each APU 106 in case that each APU 106 respectively takes charge of different processing. As shown in FIG. 15, if each APU 106 takes charge of different processing, while the first APU 106a executes processing of the first stage for a slice 1, the second APU 106a cannot execute processing of the second stage for the slice 1, i.e., the second APU 106a is under a condition of stand-by. In this way, if a plurality of APUs 106 respectively executes different processing, till one APU 106 completes processing of a slice, another APU 106 cannot begin to execute processing of the slice, and processing efficiency falls. Briefly, if a plurality of APUs 106 takes charge of different processing, in spite of parallel processing of the plurality of APUs 106, processing cannot be efficiently executed.

Accordingly, as explained by referring to FIG. 14, each APU 106 executes the same processing (same stage) for a different slice. In this case, frequency of stand-by condition in each APU 106 is reduced, and processing can be effectively executed.

Components and processing of the bit rate conversion apparatus 10 of the second embodiment are same as in the first embodiment. In the bit rate conversion apparatus 10 of the second embodiment, in the same way as in the first embodiment, rate control is executed using analysis data acquired from the PU 102.

In the bit rate conversion apparatus 10 of the second embodiment, the first APU 106a determines generated bit of each picture or each slice. Accordingly, the first APU 106a may create analysis data including the generated bit. In this case, the second APU 106b and the third APU 106c may execute rate control using the analysis data (created by the first APU 106a). Concretely, the second APU 106b and the third APU 106c acquire the analysis data through the DMAC 104.

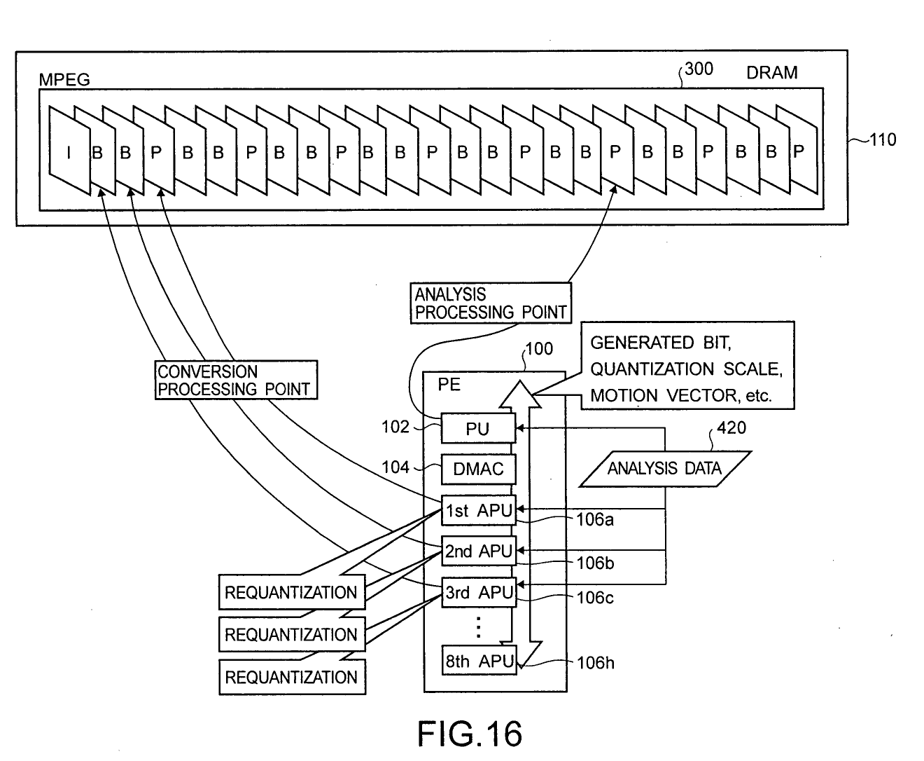

Next, the bit rate conversion apparatus 10 of the third embodiment is explained. FIG. 16 is a schematic diagram of processing of the bit rate conversion apparatus 10 according to the third embodiment. In the third embodiment, each APU 106a-106h acquires analysis data 420 of part data not processed by the APU 106 (unprocessed part data) in moving picture encoded data 300, and converts bit rate of the part data using the analysis data 420.

In comparison with conversion processing of the APU 106, syntax analysis of the PU 102 hardly includes much less operation processing, and quick processing is possible. Accordingly, a processing position of the PU 102 in moving picture encoded data 300 can sufficiently advance in comparison with a processing position of the APU 106. As shown in FIG. 16, when a position of syntax analysis of the PU 102 in the moving picture encoded data 300 advances faster than a position of bit rate conversion of the APU 106 in the moving picture encoded data 300, the APU 106 can previously acquire analysis data 420 of part data not processed by the APU 106 (unprocessed part data) in the moving picture encoded data.

In this way, in moving picture encoded data, rate control is executed using analysis data of unprocessed part data of which position advances faster than a position of part data as present object of bit rate conversion. In this case, accuracy of rate control improves. Furthermore, the more a position of syntax analysis processing advances, the more analysis data used for rate control is acquired. Accordingly, one path rate control can be executed in the same way as two paths rate control, and bit rate conversion can be executed with high image quality.

Especially, in order to raise processing speed of syntax analysis of the PU 102, for example, the syntax analysis unit 202 may detect a picture start code only. In this case, a position of syntax analysis of the PU 102 can advance faster than a position of bit rate conversion of the APU 106.

In case of detecting the picture start code only, a generated bit assigned to each picture is acquired while information by unit of slice or by unit of macro block is not acquired. However, generated bit of each picture is very important information for variable bit rate conversion. Accordingly, in case of utilizing the picture start code, bit rate conversion can be executed with high speed.

Components and processing of the bit rate conversion apparatus 10 of the third embodiment are same as in the first embodiment.

As mentioned-above, in the present invention, the main processor executes data analysis processing of which operation quantity is small while the sub processor executes conversion processing such as requantization of which operation quantity is large. Accordingly, bit rate conversion can be executed with high speed.

In the disclosed embodiments, the processing can be accomplished by a computer-executable program, and this program can be realized in a computer-readable memory device.

In the embodiments, the memory device, such as a magnetic disk, a flexible disk, a hard disk, an optical disk (CD-ROM, CD-R, DVD, and so on), an optical magnetic disk (MD and so on) can be used to store instructions for causing a processor or a computer to perform the processes described above.

Furthermore, based on an indication of the program installed from the memory device to the computer, OS (operation system) operating on the computer, or MW (middle ware software), such as database management software or network, may execute one part of each processing to realize the embodiments.

Furthermore, the memory device is not limited to a device independent from the computer. By downloading a program transmitted through a LAN or the Internet, a memory device in which the program is stored is included. Furthermore, the memory device is not limited to one. In the case that the processing of the embodiments is executed by a plurality of memory devices, a plurality of memory devices may be included in the memory device. The component of the device may be arbitrarily composed.

A computer may execute each processing stage of the embodiments according to the program stored in the memory device. The computer may be one apparatus such as a personal computer or a system in which a plurality of processing apparatuses are connected through a network. Furthermore, the computer is not limited to a personal computer. Those skilled in the art will appreciate that a computer includes a processing unit in an information processor, a microcomputer, and so on. In short, the equipment and the apparatus that can execute the functions in embodiments using the program are generally called the computer.

Other embodiments of the invention will be apparent to those skilled in the art from consideration of the specification and practice of the invention disclosed herein. It is intended that the specification and examples be considered as exemplary only, with the true scope and spirit of the invention being indicated by the following claims.

What is claimed is:

1. An apparatus for converting a bit rate of encoded moving picture data, comprising:
a main processor configured to control bit rate conversion;
at least one sub processor configured to execute the bit rate conversion based on an indication from said main processor;
a main memory configured to store the encoded moving picture data; and
a memory access controller configured to control data transfer between said main memory and said main processor and between said main memory and said at least one sub processor;
wherein said main processor comprises:
a moving picture data acquisition unit configured to acquire the encoded moving picture data from said main memory through said memory access controller;
a data analysis unit configured to analyze the encoded moving picture data; and
an analysis data creation unit configured to create analysis data based on an analysis result of said data analysis unit;
wherein said at least one sub processor comprises:
an analysis data acquisition unit configured to acquire the analysis data; and
a conversion processing unit configured to convert the bit rate of the encoded moving picture data based on the analysis data.

2. The apparatus according to claim 1,
wherein said main processor further comprises
a part data specification unit configured to specify part data in the encoded moving picture data based on a throughput of said at least one sub processor;
a part data notification unit configured to notify said at least one sub processor of the part data; and
wherein said at least one sub processor further comprises
a data acquisition unit configured to acquire the part data;
wherein said conversion processing unit converts the bit rate of the part data.

3. The apparatus according to claim 2,
wherein said at least one sub processor further comprises a local memory; and
wherein said part data specification unit specifies part data based on a capacity of the local memory.

4. The apparatus according to claim 2,
wherein said part data specification unit specifies an address corresponding to a division point of the part data in the encoded moving picture data, and
wherein said part data notification unit notifies said at least one sub processor of the address.

5. The apparatus according to claim 1, 2, 3 or 4,
wherein said conversion processing unit executes a requantization and a variable length encoding as the bit rate conversion.

6. The apparatus according to claim 2,
wherein, in a first sub processor,
said data acquisition unit acquires the encoded moving picture data, and
said conversion processing unit executes a first processing of the bit rate conversion of the encoded moving picture data,
and wherein, in a second sub processor,
said analysis data acquisition unit acquires a first conversion data generated from the first processing by said first sub processor, and
said conversion processing unit executes a second processing of bit rate conversion using the first conversion data to the encoded moving picture data after the first processing.

7. The apparatus according to claim 6,
wherein, in the first sub processor,
said conversion processing unit generates a baseband image by decoding the encoded moving picture data as the first processing, and wherein, in the second sub processor,
said analysis data acquisition unit acquires the first conversion data including the baseband image, and
said conversion processing unit re-encodes the baseband image as the second processing.

8. The apparatus according to claim 7,
wherein, in the first sub processor,
said conversion processing unit creates analysis data including generated bit data used for encoding the baseband image based on the first processing,
and wherein, in the second sub processor,
said conversion processing unit encodes the baseband image based on the generated bit data.

9. The apparatus according to claim 1,
wherein the encoded moving picture data includes information of generated bit data which was used for encoding the moving picture data,
wherein, in said main processor,
said data analysis unit extracts the information of generated bit data from the encoded moving picture data, and
said analysis data creation unit creates analysis data including the generated bit data,
and wherein, in said at least one sub processor,
said conversion processing unit executes bit rate conversion of the encoded moving picture data based on the generated bit data.

10. The apparatus according to claim 9,
wherein the encoded moving picture data includes information of generated bit data which was used for encoding each picture of the moving picture data.

11. The apparatus according to claim 9,
wherein the encoded moving picture data includes information of generated bit data which was used for encoding each slice or each video packet of the moving picture data.

12. The apparatus according to claim 9,
wherein the encoded moving picture data includes information of generated bit data which was used for encoding each macro block of the moving picture data.

13. The apparatus according to claim 1,
wherein the encoded moving picture data includes a quantization scale which was used for encoding the moving picture data,
wherein, in said main processor,
said data analysis unit extracts the quantization scale from the encoded moving picture data, and
said analysis data creation unit creates analysis data including the quantization scale,
and wherein, in said at least one sub processor,
said conversion processing unit executes quantization processing of the encoded moving picture data based on the quantization scale.

14. The apparatus according to claim 13,
wherein the encoded moving picture data includes the quantization scale which was used for encoding each picture of the moving picture data.

15. The apparatus according to claim 13,
wherein the encoded moving picture data includes the quantization scale which was used for encoding each slice or each video packet of the moving picture data.

16. The apparatus according to claim 13,
wherein the encoded moving picture data includes the quantization scale which was used for encoding each macro block of the moving picture data.

17. The apparatus according to claim 1,
wherein the encoded moving picture data includes a motion vector which was used for encoding each macro block of the moving picture data,
wherein, in said main processor,
said data analysis unit extracts the motion vector from the encoded moving picture data, and
said analysis data creation unit creates analysis data including the motion vector,
and wherein, in said at least one sub processor,
said conversion processing unit executes motion compensation based on the motion vector.

18. The apparatus according to claim 1,
wherein, in the sub processor,
said analysis data acquisition unit acquires analysis data of unprocessed part data in the moving picture data, and
said conversion processing unit converts bit rate of the unprocessed part data based on the analysis data.

19. A method for converting a bit rate of encoded moving picture data stored in a system including a main processor and at least one sub processor, comprising:
acquiring the encoded moving picture data in the main processor;
analyzing the encoded moving picture data in the main processor;
creating analysis data based on an analysis result in the main processor;
acquiring the analysis data and the encoded moving picture data in the at least one sub processor; and
converting the bit rate of the encoded moving picture data based on the analysis data in the at least one sub processor.

20. A computer program product, comprising:
a computer readable program code embodied in said product for causing a computer to convert a bit rate of encoded moving picture data stored in a system including a main processor and at least one sub processor, said computer readable program code comprising:
a first program code to acquire the encoded moving picture data in the main processor;
a second program code to analyze the encoded moving picture data in the main processor;
a third program code to create analysis data based on an analysis result in the main processor;
a fourth program code to acquire the analysis data and the encoded moving picture data in the at least one sub processor; and
a fifth program code to convert the bit rate of the encoded moving picture data based on the analysis data in the at least one sub processor.
